(19) United States
(12) Patent Application Publication
(10) Pub. No.: US 2025/0379169 A1
(43) Pub. Date: Dec. 11, 2025

(54) SEMICONDUCTOR SUBSTRATES, SEMICONDUCTOR PACKAGES INCLUDING SEMICONDUCTOR SUBSTRATE AND METHODS FOR MANUFACTURING THE SAME

(71) Applicant: Samsung Electronics Co., Ltd., Suwon-si (KR)

(72) Inventor: YOUNGMIN YUN, Suwon-si (KR)

(21) Appl. No.: 18/978,565

(22) Filed: Dec. 12, 2024

(30) Foreign Application Priority Data
Jun. 7, 2024 (KR) 10-2024-0074437

(51) Int. Cl. H01L 23/00

(52) U.S. Cl. CPC H01L 24/06; H01L 24/05; H01L 24/03; H01L 2224/03462; H01L 2224/0347; H01L 2224/0401; H01L 2224/05571; H01L 2224/0603; H01L 2224/06051; H01L 2224/06102; H01L 2224/06132

(57) ABSTRACT

A semiconductor substrate includes a substrate base, wherein the substrate base includes a first region and a second region around the first region, and the first region and the second region are defined as sections of a reference plane of the substrate base; a plurality of first connection pads in the first region, wherein an upper surface of each of the plurality of first connection pads has a first area in a horizontal direction, and each of the plurality of first connection pads has a first height in a vertical direction; and a plurality of second connection pads in the second region, wherein an upper surface of each of the plurality of second connection pads has a second area in the horizontal direction, and each of the plurality of second connection pads has a second height in the vertical direction, the first area is larger than the second area, and the first height is less than the second height.

### CROSS-REFERENCE TO RELATED APPLICATION

This application claims priority to and the benefit of Korean Patent Application No. 10-2024-0074437 filed in the Korean Intellectual Property Office on Jun. 7, 2024, the entire contents of which are incorporated herein by reference.

### FIELD

The present disclosure relates to semiconductor substrates, semiconductor packages including a semiconductor substrate, and manufacturing methods thereof.

### BACKGROUND

A surface mount technology (SMT) is a technology that attaches a semiconductor die to a connection pattern formed on a surface of a printed circuit board (PCB). When performing the surface mounting technology (SMT), a bump is used as an intermediate medium to electrically connect the semiconductor die and the connection pattern on the printed circuit board (PCB), as a technology for arranging such bumps, a flip chip ball grid array (FC-BGA) technology, which connects the semiconductor die and the printed circuit board (PCB) by arranging the bumps as a lattice, is well known. The FC-BGA technology has a feature of arranging the bumps across the entire connection surface to transmit and receive the maximum input and output signals required by the semiconductor die.

Based on this FC-BGA technology, recently, products applying a mixed bump of which a center region and a peripheral area are distinguished using the plane of the substrate as a reference, and the size of the bumps placed in the center region is reduced, and the size of the bumps placed in the peripheral area is increased, are being developed. In addition, the products are being developed that do not apply a pre-solder, which may cause cracks between different materials, to the FC-BGA technology.

In the products where the mixed bumps are applied and no pre-solder is applied, because the size of the connection pad of the semiconductor die in the peripheral area is smaller than the size of the connection pad of the semiconductor die in the central region, the volume of the solder in contact with the connection pad of the semiconductor die in the peripheral area is smaller than the volume of the solder in contact with the connection pad of the semiconductor die in the central region. Due to this difference between the volumes of the solder, after the surface mounting technology (SMT) is performed, the gap between the semiconductor die and the substrate in the central region becomes large, and the gap cannot be filled in the peripheral area, resulting in poor connection.

### SUMMARY

A semiconductor substrate and a semiconductor package of which a first area of an upper surface of each of first connection pads on the central region of the substrate is larger than a second area of an upper surface of each of second connection pads on the peripheral area of the substrate, and a first height of each of the first connection pads is less than a second height of each of the second connection pads, and a semiconductor package may be provided.

A semiconductor substrate and a semiconductor package in which each of first connection pads on a central region of a substrate includes a recessed region and a non-recessed region, a first area of each plane of the first connection pads is larger than a second area of the upper surface of each of the second connection pads on a peripheral area of the substrate, and a first height in each recessed region of the first connection pads is less than a second height in each of the second connection pads, may be provided.

A semiconductor substrate according to some embodiments includes a substrate base, wherein the substrate base includes a first region and a second region around the first region, and the first region and the second region are defined as sections of a reference plane of the substrate base; a plurality of first connection pads in the first region, wherein an upper surface of each of the plurality of first connection pads has a first area in a horizontal direction, and each of the plurality of first connection pads has a first height in a vertical direction; and a plurality of second connection pads in the second region, wherein an upper surface of each of the plurality of second connection pads has a second area in the horizontal direction, and each of the plurality of second connection pads has a second height in the vertical direction, the first area is larger than the second area, and the first height is less than the second height.

A semiconductor substrate according to some embodiments includes a substrate base, wherein the substrate base includes a first region and a second region around the first region, and the first region and the second region are defined as sections of a reference plane of the substrate base; a plurality of first connection pads on the first region, wherein each of the plurality of first connection pads includes a recessed region and a non-recessed region around the recessed region, and the recessed region and the non-recessed region are defined as sections of a plane of each of the plurality of first connection pads, each plane of the plurality of first connection pads has a first area in a horizontal direction, and each of the plurality of first connection pads has a first height in a vertical direction on the recessed region; a plurality of second connection pads on the second region, wherein un upper surface of each of the plurality of second connection pads has a second area in the horizontal direction, and each of the plurality of second connection pads has a second height in the vertical direction; and an insulating member on the substrate base, on the plurality of first connection pads, and on the plurality of second connection pads, wherein the insulating member includes a plurality of through holes, and each of the plurality of first connection pads or each of the plurality of second connection pads is exposed through a respective one of the plurality of through holes, the first area is larger than the second area, and the first height is less than the second height.

A semiconductor package according to some embodiments includes a semiconductor substrate, wherein the semiconductor substrate includes a substrate base including a first region and a second region around the first region, and the first region and the second region are defined as sections of a reference the plane of the substrate base; a plurality of first connection pads on the first region, wherein an upper surface of each of the plurality of first connection pads has a first area in a horizontal direction, and each of the plurality of first connection pads has a first height in a vertical direction; and a plurality of second connection pads on the second region, wherein the upper surface of each of the plurality of second connection pads has a second area in the horizontal direction, and each of the plurality of second connection pads has a second height in the vertical direction, the first area is larger than the second area, and the first height is less than the second height, a semiconductor die on the semiconductor substrate, wherein the semiconductor die includes a plurality of third connection pads and a plurality of fourth connection pads; a plurality of first connection members between the semiconductor substrate and the semiconductor die, wherein each of the plurality of first connection members connects a respective one of the plurality of first connection pads and a respective one of the plurality of third connection pads; and a plurality of second connection members between the semiconductor substrate and the semiconductor die, wherein each of the plurality of second connection members connects a respective one of the plurality of second connection pads to a respective one of the plurality of fourth connection pads.

By reducing the height of each of the connection pads in the central region of the substrate, the difference of the gap size between the semiconductor die and the substrate in the central region and the gap size between the semiconductor die and the substrate in the peripheral area may be reduced and, as a result, a connection reliability between the semiconductor die and the substrate may be secured or improved.

### BRIEF DESCRIPTION OF THE DRAWINGS

FIG. 1 is a cross-sectional view of a substrate of according to some embodiments taken along the line A-A of FIG. 2.

FIG. 2 is a top plan view showing an upper surface of the substrate of FIG. 1.

FIGS. 3-8 are cross-sectional views illustrating methods of manufacturing the substrate of FIG. 1.

FIG. 9 is a cross-sectional view of a semiconductor package according to some embodiments including the substrate of FIG. 1.

FIG. 10 is a cross-sectional view of a substrate according to further embodiments.

FIGS. 11-15 are cross-sectional views illustrating methods of manufacturing the substrate of FIG. 10.

FIG. 16 is a cross-sectional view of a semiconductor package according to some embodiments including the substrate of FIG. 10.

FIG. 17 is a cross-sectional view of a semiconductor package according to further embodiments.

FIG. 18 is a cross-sectional view of a substrate according to further embodiments.

FIGS. 19-22 are cross-sectional views illustrating methods of manufacturing the substrate of FIG. 18.

FIG. 23 is a cross-sectional view of a semiconductor package according to some embodiments including the substrate of FIG. 18.

FIG. 24 is a cross-sectional view of a semiconductor package according to further embodiments.

FIG. 25 is a cross-sectional view of a semiconductor package according to further embodiments.

FIG. 26 is a cross-sectional view of a substrate according to further embodiments.

FIG. 27 is an enlarged cross-sectional view of a region B in FIG. 26.

FIGS. 28-37 are cross-sectional views illustrating methods of manufacturing the substrate of FIG. 26.

FIG. 38 is a cross-sectional view of a semiconductor package according to further embodiments.

FIG. 39 is a cross-sectional view of a semiconductor package according to further embodiments.

### DETAILED DESCRIPTION

The present disclosure will be described more fully hereinafter with reference to the accompanying drawings, in which exemplary embodiments of the disclosure are shown. As those skilled in the art would realize, the described embodiments may be modified in various different ways, all without departing from the spirit or scope of the present disclosure.

In the drawings, the thickness of layers, films, panels, regions, etc., are exaggerated for clarity, and like reference numerals designate like elements throughout the specification.

The size and thickness of the configurations are optionally shown in the drawings for convenience of description, and the present disclosure is not limited to the drawings.

Throughout this specification and the claims that follow, when it is described that an element is “coupled” or “connected” to another element, the element may be directly coupled or directly connected to the other element or indirectly coupled or indirectly connected to the other element through a third element. In addition, unless explicitly described to the contrary, the word “comprise”, and variations such as “comprises” or “comprising”, will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

Further, in this specification, the word “on a plane” means viewing a target portion from the top, and the word “on a cross section” means viewing a cross section formed by vertically cutting a target portion from the side.

It will be understood that, although the terms “first,” “second,” and/or “third” may be used herein to describe various materials, layers, regions, pads, electrodes, patterns, structure and/or processes, these various materials, layers, regions, pads, electrodes, patterns, structure and/or processes should not be limited by these terms. These terms are only used to distinguish one material, layer, region, pad, electrode, pattern, structure or process from another material, layer, region, pad, electrode, pattern, structure or process. Thus, “first”, “second” and/or “third” may be used selectively or interchangeably in describing each material, layer, region, electrode, pad, pattern, structure or process.

Hereinafter, example embodiments of a semiconductor substrate 110, a semiconductor package 100, and a manufacturing method thereof will be described with reference to accompanying drawings.

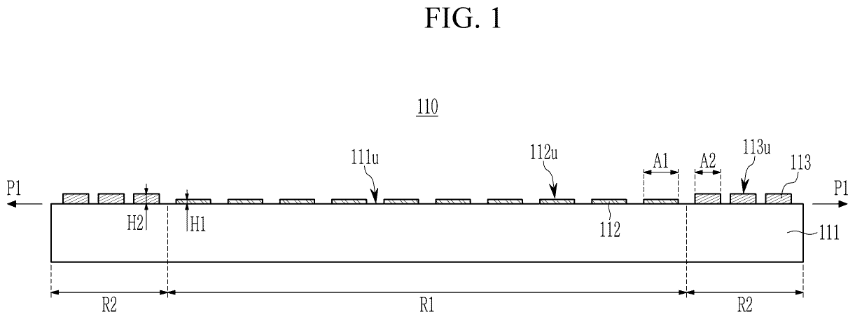

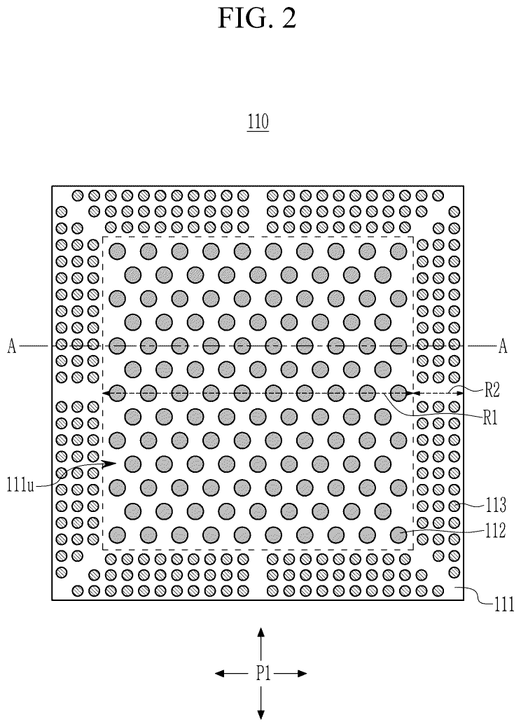

FIG. 1 is a cross-sectional view showing a substrate 110 according to some embodiments. FIG. 1 is a cross-sectional view of the substrate 110 as shown in FIG. 2 taken along the line A-A of FIG. 2.

Referring to FIG. 1, according to some embodiments the substrate 110 is a semiconductor substrate. The semiconductor substrate 110 may include a substrate base 111, a plurality of first connection pads 112, and a plurality of second connection pads 113. In some embodiments, the substrate 110 may include a printed circuit board (PCB), an embedded trace substrate (ETS), a board, an interposer, or a bridge die.

The substrate base 111 may include wiring patterns therein. The substrate base 111 protects and insulates the wiring patterns. The first connection pads 112 and the second connection pads 113 may be disposed on the upper surface 111u of the substrate base 111. A solder resist and solder balls may be placed on the bottom surface of the substrate base 111. The substrate base 111 may include a central region or first region R1 and a peripheral region or second region R2 around the central region R1. The central region R1 and the peripheral region R2 are defined by dividing a reference plane P1 of the substrate base 111. That is, the reference plane P1 is sectioned into two mutually exclusive sections or regions R1 and R2. The reference plane P1 may be orthogonal to the thickness of the substrate base 111 and the heights of the first and second connection pads 112, 113. The reference plane P1 may be regarded as a horizontal plane. In some embodiments, the reference plane P1 is the plane defined by the upper surface 111u of the substrate base 111.

The substrate base 111 may include a dielectric. In some embodiments, the dielectric may include a thermosetting resin such as epoxy resin, a thermoplastic resin such as polyimide, or a material in which these resins are mixed with an inorganic filler. In some embodiments, the dielectric may include a resin impregnated in a core material such as a glass fiber (a glass fiber, a glass cloth, a glass fabric), or a material in which these resins are mixed with an inorganic filler. In some embodiments, the dielectric may include prepreg, ajinomoto build-up film (ABF), FR-4, or Bismaleimide Triazine (BT). In some embodiments, the dielectric may include a photoimageable a dielectric (PID).

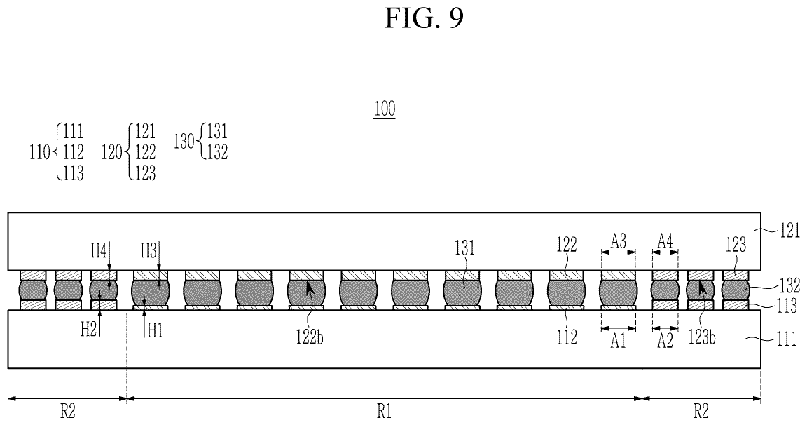

The first connection pads 112 are located on the upper surface 111u of the substrate base 111. The first connection pads 112 are located in the central region R1. The first connection pads 112 protrude from the substrate base 111. Each of the first connection pads 112 is disposed between respective wirings inside the substrate base 110 and a respective of the first connection members 131 (referring to FIG. 9). Each of the first connection pads 112 electrically connects a respective one of the first connection members 131 to respective wirings inside the substrate base 111. The second connection pads 113 are disposed on the upper surface 111u of the substrate base 111. The second connection pads 113 are located in the peripheral region R2. The second connection pads 113 protrude from the substrate base 111. Each of the second connection pads 113 is disposed between respective wirings inside the substrate base 110 and a respective one of the second connection members 132 (see FIG. 9). Each of the second connection pads 113 electrically connects a respective one of the second connection members 132 to a respective one of the wirings inside the substrate base 111.

Each of the first connection pads 112 has an upper surface 112u. The upper surface 112u of each first connection pad 112 has a first area A1 in a horizontal direction or plane. Each of the first connection pads 112 has a first thickness or height H1 in a vertical direction. Each of the second connection pads 113 has an upper surface 113u. The upper surface 113u of each second connection pad 113 has a second area A2 in the horizontal direction or plane. Each of the second connection pads 113 has a second thickness or height H2 in the vertical direction. The first area A1 is larger than the second area A2, and the first height H1 is less than the second height H2. In some embodiments, the first connection pads 112 and the second connection pads 113 may each include at least one of copper, aluminum, silver, tin, gold, nickel, lead, titanium, and alloys thereof. In other embodiments, the substrate 110 includes fewer or more connection pads 112, 113 than illustrated in FIG. 2.

FIG. 2 is a top plan view showing an upper surface of the substrate 110 in FIG. 1.

Referring to FIG. 2, the substrate base 111 includes the central region R1 and the peripheral region R2 around the central region R1. As discussed above, the central region R1 and the peripheral region R2 are defined by dividing the reference plane P1 of the substrate base 111. The central region R1 may be a region connected to the electric power circuit patterns of the semiconductor die 120 (referring to 9) disposed on the substrate 110. The peripheral region R2 may be a region connected to the signal circuit patterns of the semiconductor die 120 disposed on the substrate 110. The first connection pads 112 are located in the central region R1. The second connection pads 113 are located in the peripheral region R2. In FIG. 2, the planar shape of the first connection pads 112 and the second connection pads 113 is shown to be circular, but it is not limited thereto, and the planar shape of the first connection pads 112 and the second connection pads 113 may be oval, quadrangle, hexagon, or polygon, for example.

In the central region R1, each of the first connection pads 112 may route an electric power transmitted to the semiconductor die 120 disposed on the substrate 110. In order to reduce losses in the process of transmitting the electric power and improve a power integrity (PI), in terms of the power integrity (PI), it is advantageous for each of the first connection pads 112 to has a larger plane size than a plane size of each of the second connection pads 113.

In the peripheral region R2, each of the second connection pads 113 may route the signal transmitted to the semiconductor die 120 disposed on the substrate 110 or transmitted from the semiconductor die 120. As a circuit integration within the semiconductor die 120 increases, a greater number of the signal wire lines are required, and according to this requirement, each of the second connection pads 113 may be designed to have a smaller plane size than a plane size of each of the first connection pads 112, so that the number of the second connection pads 113 placed on the substrate 110 may be increased.

For this reason, the upper surface 112u of each of the first connection pads 112 may be designed to have the first area A1 larger than the second area A2 of the upper surface 113u of each of the second connection pads 113. Also, referring to FIG. 9, as the same reason, the size of each of the third connection pads 122 of the semiconductor die 120 positioned in the central region R1 of the substrate 110 may be designed to be larger than the size of each of the fourth connection pads 123 of the semiconductor die 120 positioned in the peripheral region R2 of the substrate 110.

However, when the size of each of the third connection pads 122 of the semiconductor die 120 positioned in the central region R1 of the substrate 110 is larger than the size of each of the fourth connection pads 123 of the semiconductor die 120 positioned in the peripheral region R2 of the substrate 110, there is a volume difference between the solder below each of the third connection pads 122 and the solder below each of the fourth connection pads 123. The large amount of the solder below each of the third connection pads 122 expands the gap size between the substrate 110 and the semiconductor die 120 in the central region R1, and the gap in the peripheral region R2 cannot be filled with the relatively small amount of the solder below each of the fourth connection pads 123, a poor connection (e.g., a non-wet or a crack, etc.) between the second connection pads 113 of the substrate 110 and the fourth connection pads 123 of the semiconductor die 120 may occur in the peripheral region R2.

According to the present disclosure, as the first height H1 of each of the first connection pads 112 may be designed to be less than the second height H2 of each of the second connection pads 113, the gap size between the substrate 110 and the semiconductor die 120 in the central region R1 may be reduced, and the connection reliability between the substrate 110 and the semiconductor die 120 may be secured.

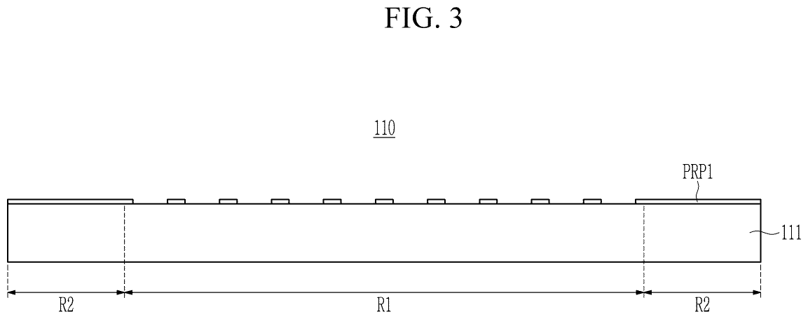

FIGS. 3-8 are cross-sectional views to explain methods of manufacturing the substrate 110 of FIG. 1.

FIG. 3 is a cross-sectional view showing a step of forming a first photoresist pattern PRP1 on the substrate base 111.

Referring to FIG. 3, a barrier layer may be formed on the substrate base 111. In some embodiments, the barrier layer may include at least one of titanium, titanium nitride, tantalum, and tantalum nitride. The barrier layer prevents conductive materials constituting a seed metal layer or the first connection pads 112 from diffusing into the substrate base 111. In some embodiments, the barrier layer may be formed by performing a physical vapor deposition (PVD) process. In some embodiments, the barrier layer may be formed by performing a sputtering process.

After this, the seed metal layer may be formed on the barrier layer. In an embodiment, the seed metal layer may include copper. In some embodiments, the seed metal layer may be formed by an electroless plating. In some embodiments, a cleaning process or a metal catalyst activation pretreatment process may be performed prior to the electroless plating. In some embodiments, the seed metal may be formed by performing a sputtering process.

Next, a photoresist is formed on the seed metal layer. In some embodiments, the photoresist may be formed through a spin coating. In some embodiments, the photoresist may include an organic polymer resin including a photosensitivity (a photoactive) material.

Next, the photoresist is exposed and developed to form the first photoresist pattern PRP1. The first photoresist pattern PRP1 includes openings, each of which may have a shape of an oval, quadrangle, hexagon, or polygon.

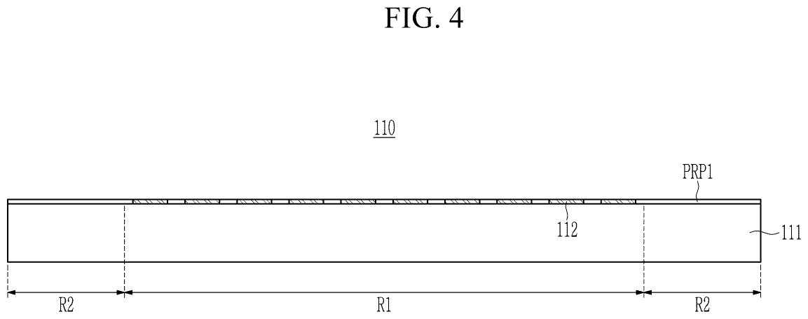

FIG. 4 is the cross-sectional view showing a step of forming each of the first connection pads 112 within each of the openings of the first photoresist pattern PRP1.

Referring to FIG. 4, each of the first connection pads 112 is formed within a respective one of the openings of the first photoresist pattern PRP1. In some embodiments, the first connection pads 112 may be formed by an electroplating. The first connection pads 112 are formed by growing a metal layer from the seed metal layer formed first by the electroplating. In some embodiments, after the first connection pads 112 are formed, an annealing process may be performed. In some embodiments, the first connection pads 112 may include copper.

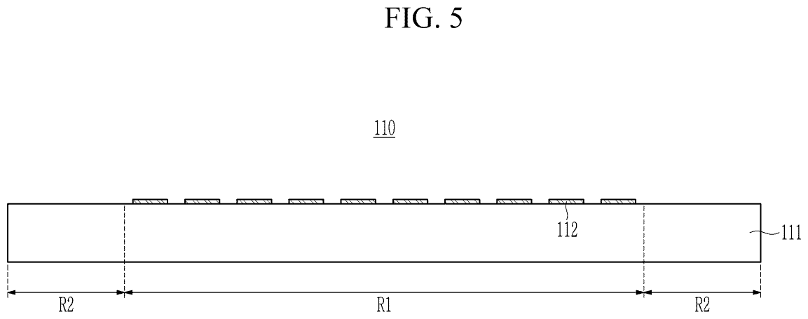

FIG. 5 is a cross-sectional view showing a step to remove the first photoresist pattern PRP1.

Referring to FIG. 5, the first photoresist pattern PRP1 is removed. In some embodiments, the first photoresist pattern PRP1 may be removed by at least one of etching, ashing, and stripping.

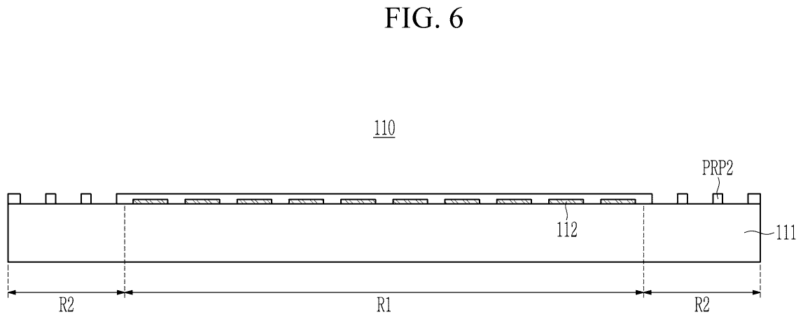

FIG. 6 is a cross-sectional view showing a step in forming a second photoresist pattern PRP2.

Referring to FIG. 6, a photoresist is formed on the seed metal layer. In some embodiments, the photoresist may be formed through a spin coating. In some embodiments, the photoresist may include an organic polymer resin including a photosensitive material.

Next, a photoresist is exposed and developed to form the second photoresist pattern PRP2. The second photoresist pattern PRP2 includes openings, each opening may have the shape of an oval, quadrangle, hexagon, or polygon, for example.

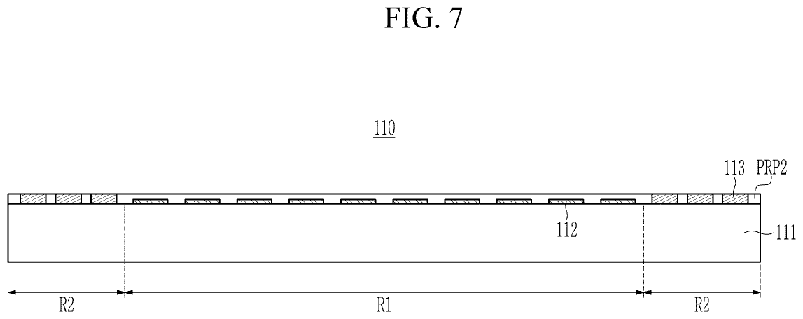

FIG. 7 is a cross-sectional view showing a step of forming each of the second connection pads 113 within each of the openings of the first photoresist pattern PRP2.

Referring to FIG. 7, each of the second connection pads 113 is formed within a respective one of the openings of the first photoresist pattern PRP1. In some embodiments, the second connection pads 113 may be formed by an electroplating. The second connection pads 113 are formed by growing a metal layer from the seed metal layer formed first by the electroplating. In some embodiments, an annealing process may be performed after the second connection pads 113 are formed. In some embodiments, the second connection pads 113 may include copper.

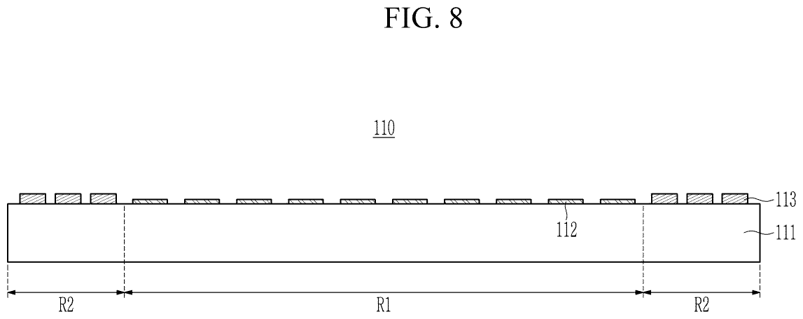

FIG. 8 is a cross-sectional view showing a step for removing the second photoresist pattern PRP2.

Referring to FIG. 8, the second photoresist pattern PRP2 is removed. In some embodiments, the second photoresist pattern PRP2 may be removed by at least one of etching, ashing, and stripping.

FIG. 9 is a cross-sectional view showing a semiconductor package 100 of according to some embodiments.

Referring to FIG. 9, the semiconductor die 120 is mounted on the substrate 110 of FIG. 8 to form the semiconductor package 100. The semiconductor die 120 is mounted on the substrate 110 by performing a flip chip bonding process. The semiconductor package 100 may include the substrate 110, the first connection members 131, the second connection members 132, and the semiconductor die 120. The semiconductor package 100 may be a package manufactured based on a FC-BGA technology. The substrate 110 may be constructed as described herein with reference to FIG. 1.

The first connection members 131 are placed or located in the central region R1. The first connection members 131 are placed or located between the substrate 110 and the semiconductor die 120. Each of the first connection members 131 electrically connects a respective one of the third connection pads 122 to a respective one of the first connection pads 112. Each of the first connection members 131 may cover at least a portion of the facing side of its corresponding first connection pad 112. The first connection members 131 may route the electric power transmitted to the semiconductor die 120.

The second connection members 132 are placed or located in the peripheral region R2. The second connection members 132 are placed or located between the substrate 110 and the semiconductor die 120. Each of the second connection members 132 electrically connects a respective one of the fourth connection pads 123 to a respective one of the second connection pads 113. Each of the second connection members 132 may cover at least a portion of the facing side of its corresponding second connection pad 113. The second connection members 132 may route the signal transmitted to the semiconductor die 120 or transmitted from the semiconductor die 120.

The size of each of the first connection members 131 is larger than the size of each of the second connection members 132. In some embodiments, the first connection members 131 and the second connection members 132 may include a solder. In some embodiments, the first connection members 131 and the second connection members 132 may each include at least one of tin, silver, lead, nickel, copper, and alloys thereof. In other embodiments, the semiconductor package 100 may include fewer or more connection members than illustrated in the drawings.

The semiconductor die 120 is placed or located on the substrate 110. The semiconductor die 120 may include a die base 121, the third connection pads 122, and the fourth connection pads 123. In some embodiments, the semiconductor die 120 may include a logic die or a memory die. In some embodiments, the semiconductor die 120 may include a three dimensional integrated circuit (3DIC). In some embodiments, the semiconductor die 120 may include a system on chip (SoC), an application processor (AP), or a high bandwidth memory (HBM).

The die base 121 may include at least one of passive devices, active devices, wirings, and vias. In some embodiments, the die base 121 may include at least one of a neural processing unit (NPU), a central processing unit (CPU), a graphic processing unit (GPU), a communication chip, and a sensor.

The third connection pads 122 are placed or located on the bottom surface of die base 121. The third connection pads 122 are placed or located in the central region R1. The third connection pads 122 protrude from the die base 121. Each of the third connection pads 122 is placed between a respective wirings inside the die base 121 and a respective one of the first connection members 131. Each of the third connection pads 122 electrically connects respective wirings inside the die base 121 to a respective one of the first connection members 131. The fourth connection pads 123 are placed or located in the bottom surface of the die base 121. The fourth connection pads 123 are placed or located in the peripheral region R2. The fourth connection pads 123 protrude from the die base 121. Each of the fourth connection pads 123 is placed or located between respective wirings inside the die base 121 and a respective one of the second connection members 132. Each of the fourth connection pads 123 electrically connects the corresponding wirings inside the die base 121 to its corresponding one of the second connection members 132.

The bottom surface 122b of each of the third connection pads 122 may have a third area A3 in the horizontal direction. Each of the third connection pads 122 may have a third thickness or height H3 in the vertical direction. The bottom surface 123b of each of the fourth connection pads 123 may have a fourth area A4 in the horizontal direction. Each of the fourth connection pads 123 may have a fourth thickness or height H4 in the vertical direction. The third area A3 is larger than the fourth area A4, and the third height H3 is the same as the fourth height H4. In some embodiments, the third connection pads 122 and the fourth connection pads 123 may each include at least one of copper, aluminum, silver, tin, gold, nickel, lead, titanium, and alloys thereof. In another embodiment, the semiconductor die 120 including the fewer or more connection pads is included in the scope of the present disclosure.

As the third area A3 of the bottom surface 122b of each of the third connection pads 122 of the semiconductor die 120 positioned in the central region R1 of the substrate 110 is larger than the fourth area A4 of the bottom surface 123b of each of the fourth connection pads 123 of the semiconductor die 120 positioned in the peripheral region R2 of the substrate 110, there is a volume difference between the solder below each of the third connection pads 122 and the solder below each of the fourth connection pads 123. The first height H1 of the first connection pads 112 of the substrate 110 positioned on the central region R1 and the second height H2 of the second connection pads 113 of the substrate 110 positioned on the peripheral region R2, which are set to solve the connection defect between the second connection pads 113 of the substrate 110 and the fourth connection pads 123 of the semiconductor die 120 caused by the volume difference between the solders, may be determined by considering the volume difference between the solder below each of the third connection pads 122 and the solder below each of the fourth connection pads 123. The difference between the second height H2 and the first height H1 may increase as the difference between the third area A3 and the fourth area A4 is increased, which causes the volume differences between the solders to increase. The difference between the second height H2 and the first height H1 may increase as the difference between the first area A1 on the upper surface 112u of each of the first connection pads 112 corresponding to the third area A3 and the second area A2 on the upper surface 113u of each of the second connection pads 113 corresponding to the fourth area A4 increases.

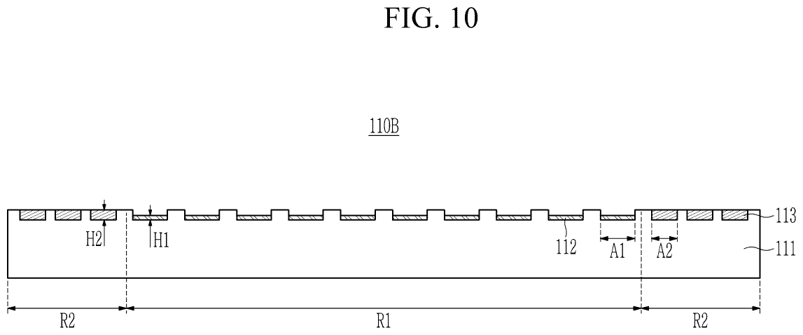

FIG. 10 is a cross-sectional view showing a substrate 110B according to further embodiments. Reference numerals used herein and labeled in FIGS. 1-9 to describe the substrate 110 and the semiconductor package 100 are also used herein and labeled in FIGS. 10-16 to designate similar or corresponding components and features of the substrate 110B and the semiconductor package 100B.

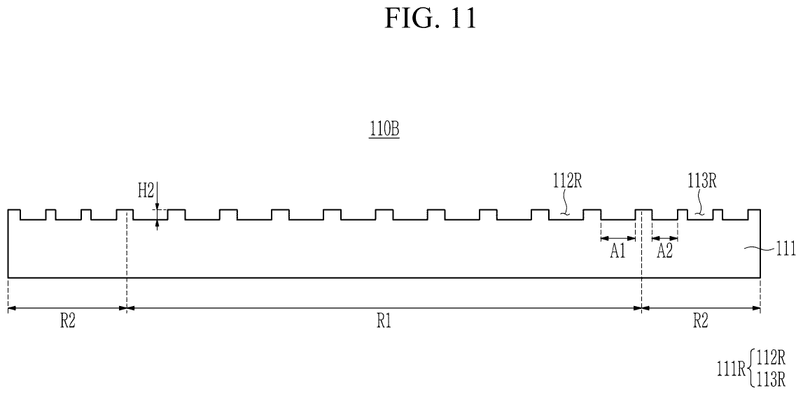

Referring to FIG. 10, the substrate 110B may include a substrate base 111, first connection pads 112, and second connection pads 113. The substrate base 111 includes recessed portions 111R (FIG. 11) on the upper surface thereof. The recessed portions 111R include first recessed portions 112R (FIG. 11) of a first region R1 and second recessed portions 113R (FIG. 11) of a second region R2.

Each of the first connection pads 112 is disposed within a respective one of the first recessed portions 112R. Side surfaces of each of the first connection pads 112 extend conformally along the inner side surfaces of the first recessed portions 112R. Side surfaces of each of the first connection pads 112 are in contact with the inner side surfaces of the first recessed portions 112R.

Each of the second connection pads 113 is disposed within a respective one of the second recessed portions 113R. Side surfaces of each of the second connection pads 113 extend conformally along the inner side surfaces of each of the second recessed portions 113R. Side surfaces of each of the second connection pads 113 are in contact with the inner side surfaces of each of the second recessed portions 113R.

For the contents other than those described in the embodiment of FIG. 10, the contents described for the semiconductor package 100 in FIG. 1 and FIG. 2 may be applied to the semiconductor package 100B.

FIG. 11 to FIG. 15 are cross-sectional views to explain a method of manufacturing a substrate 110B of FIG. 10.

FIG. 11 is a cross-sectional view showing a step of forming the first recessed portions 112R and the second recessed portions 113R on the substrate 110B.

Referring to FIG. 11, first recessed portions 112R and second recessed portions 113R are formed on a substrate 110B. In some embodiments, the first recessed portions 112R and the second recessed portions 113R may be formed by a laser drilling process or a dry etching process. The bottom surface 112b of each among the first recessed portions 112R may have a first area A1 in the horizontal direction. The inner surface of each among the first recessed portions 112R may have a second height H2 in the vertical direction. The bottom surface 113b of each among the second recessed portions 113R may have a second area A2 in the horizontal direction. The inner surface of each among the second recessed portions 113R may have a second height H2 in the vertical direction. The first area A1 is larger than the second area A2. In other embodiments, the substrate 110B includes fewer or more recessed portions.

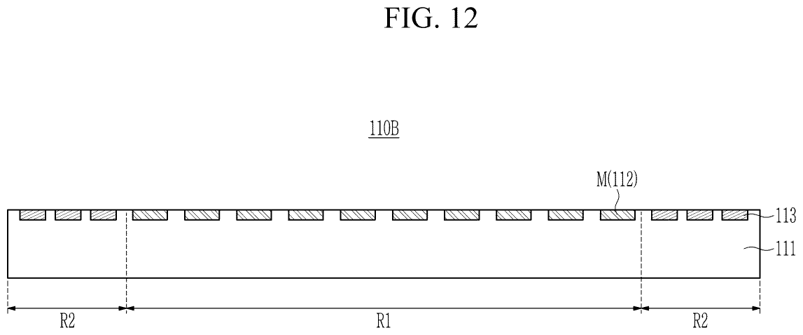

FIG. 12 is a cross-sectional view showing a step of filling a conductive material within each of the first recessed portions 112R and each of the second recessed portions 113R.

Referring to FIG. 12, a barrier layer may be formed within each of the first recessed portions 112R, each of the second recessed portions 113R, and on the upper surface of the substrate base 111. In some embodiments, the barrier layer may include at least one of titanium, titanium nitride, tantalum, and tantalum nitride. The barrier layer prevents the seed metal layer or the conductive materials constituting the first connection pads 112 and the second connection pads 113 from diffusing into the substrate base 111. In some embodiments, the barrier layer may be formed by performing a physical vapor deposition (PVD) process. In some embodiments, the barrier layer may be formed by performing a sputtering process.

After this, a seed metal layer may be formed on the barrier layer. In some embodiments, the seed metal layer may include copper. In some embodiments, the seed metal layer may be formed by an electroless plating. In some embodiments, a cleaning process or a metal catalyst activation pretreatment process may be performed prior to the electroless plating. In some embodiments, the seed metal may be formed by performing a sputtering process.

Next, a photoresist is formed on the seed metal layer. In some embodiments, the photoresist may be formed through a spin coating. In some embodiments, the photoresist may include an organic polymer resin including a photosensitive material.

After this, a photoresist pattern is formed by exposing and developing the photoresist according to the shape of the recessed portions.

Next, the openings of the photoresist pattern are filled with a conductive material M. In some embodiments, the conductive material M may be formed by electroplating. The conductive material M is formed by growing a metal layer by the electroplating from the seed metal layer formed first. In some embodiments, after the conductive material M is formed, an annealing process may be performed. In some embodiments, the conductive material M may include copper.

Next, the photoresist pattern, the exposed seed metal layer, and the exposed barrier layer are removed.

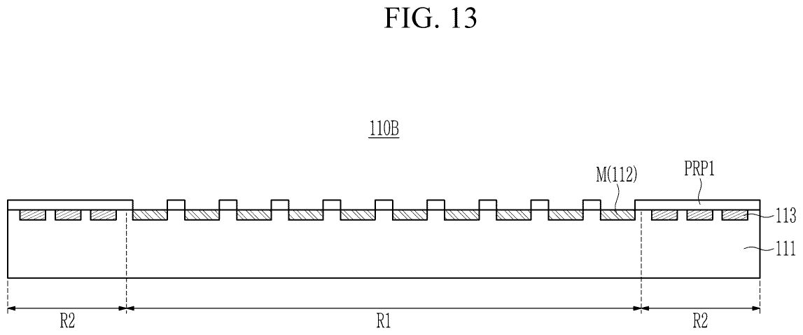

FIG. 13 is a cross-sectional view showing a step in forming a first photoresist pattern PRP1.

Referring to FIG. 13, a photoresist is formed on the upper surface of the substrate base 111 and on the conductive material M. In some embodiments, the photoresist may be formed through a spin coating. In some embodiments, the photoresist may include an organic polymer resin including a photosensitive material.

After this, the first photoresist pattern PRP1 is formed by exposing and developing the photoresist so that the conductive materials M of the first region R1 are exposed.

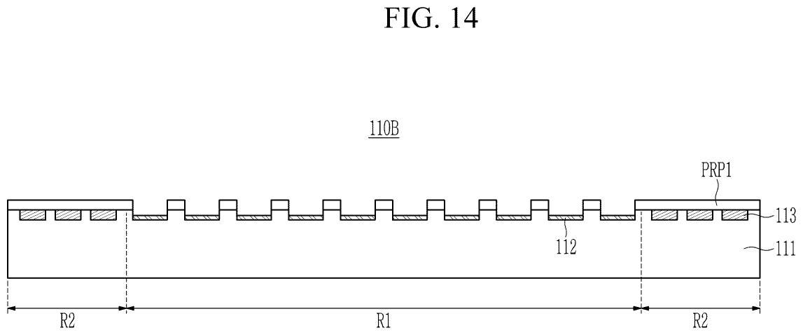

FIG. 14 is a cross-sectional view showing a step of etching the conductive materials M of the first region R1.

Referring to FIG. 14, the first connection pads 112 are formed by etching the conductive material M of the first region R1.

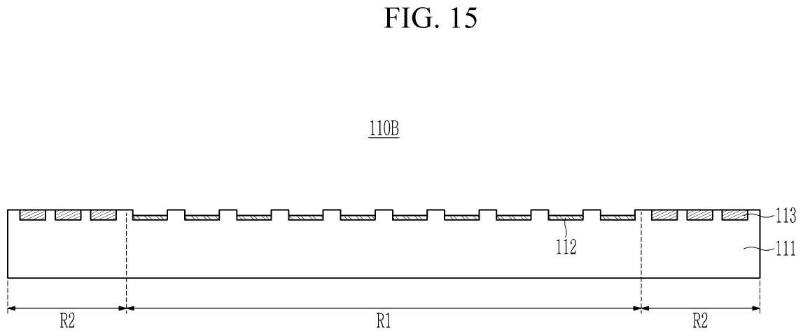

FIG. 15 is a cross-sectional view showing a step to remove the first photoresist pattern PRP1.

Referring to FIG. 15, the first photoresist pattern PRP1 is removed. In some embodiments, the first photoresist pattern PRP1 may be removed by at least one of etching, ashing, and stripping.

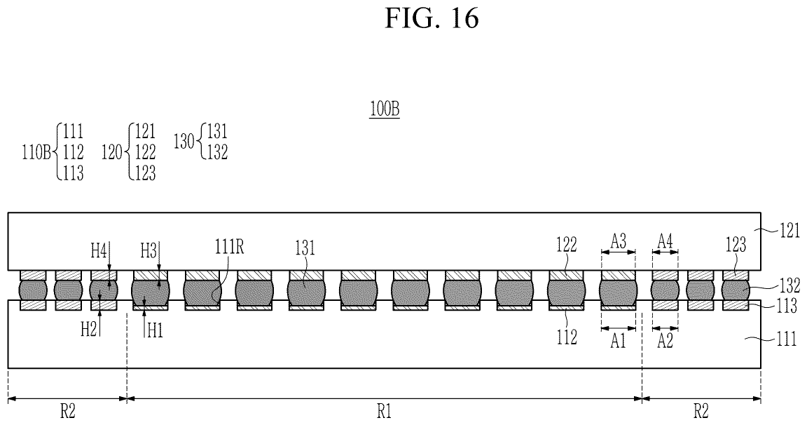

FIG. 16 is a cross-sectional view showing a semiconductor package 100B according to some embodiments.

Referring to FIG. 16, the semiconductor die 120 is mounted on the substrate 110B of FIG. 15 to form the semiconductor package 100B. The semiconductor die 120 is mounted on the substrate 110B by performing a flip chip bonding process. The semiconductor package 100B may include the substrate 110B, the first connection members 131, the second connection members 132, and the semiconductor die 120. For the first connection members 131, the second connection members 132, and the semiconductor die 120, the description above with reference to FIG. 9 may likewise apply.

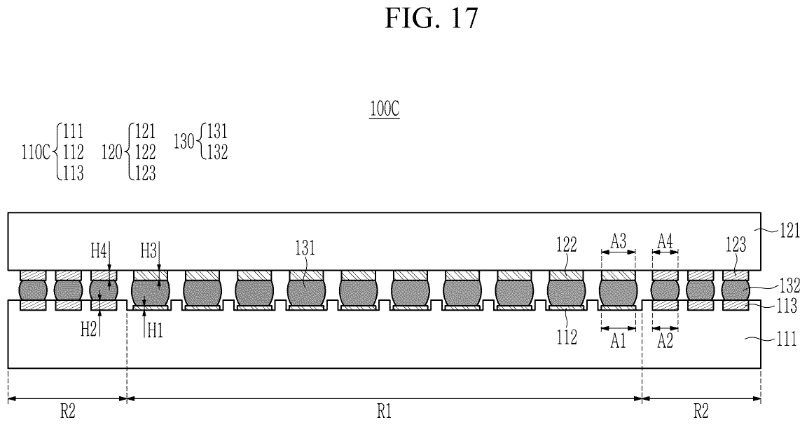

FIG. 17 is a cross-sectional view showing a semiconductor package 100C according to further embodiments. References numerals used herein and labeled in FIGS. 1-9 to describe the substrate 110 and the semiconductor package 100 are also used herein and labeled in FIG. 17 to designate similar or corresponding components and features of the substrate 110C and the semiconductor package 100C.

Referring to FIG. 17, the semiconductor package 100C may include a substrate 110C, first connection members 131, second connection members 132, and a semiconductor die 120. The substrate 110C may include a substrate base 111, first connection pads 112, and second connection pads 113. The substrate base 111 includes recessed portions 111R (FIG. 11) on the upper surface thereof. The recessed portions 111R include first recessed portions 112R (FIG. 11) of a first region R1 and second recessed portions 113R (FIG. 11) of a second region R2.

Each of the first connection pads 112 is disposed within a respective one of the first recessed portions 112R. Side surfaces of each of the first connection pads 112 are spaced apart from the inner side surfaces of each the first recessed portions 112R.

Each of the second connection pads 113 is disposed within a respective one of the second recessed portions 113R. Side surfaces of each of the second connection pads 113 extend conformally along the inner side surfaces of each of the second recessed portions 113R. Side surfaces of each of the second connection pads 113 are in contact with the inner side surfaces of each of the second recessed portions 113R.

Each of the first connection members 131 may cover at least part of the side of the corresponding one of the first connection pads 112. Each of the first connection members 131 may be in contact with the inner surface of the corresponding one of the first recessed portions 112R.

For contents other than those described in the embodiment of FIG. 17, the contents described for the substrate 110 in FIG. 10 and the contents described for the semiconductor package 100 in FIG. 9 may be applied.

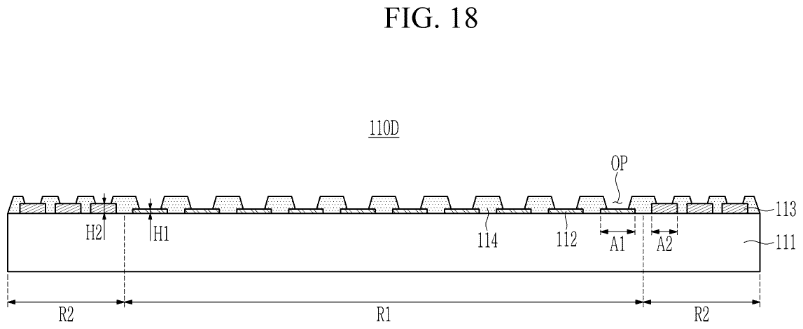

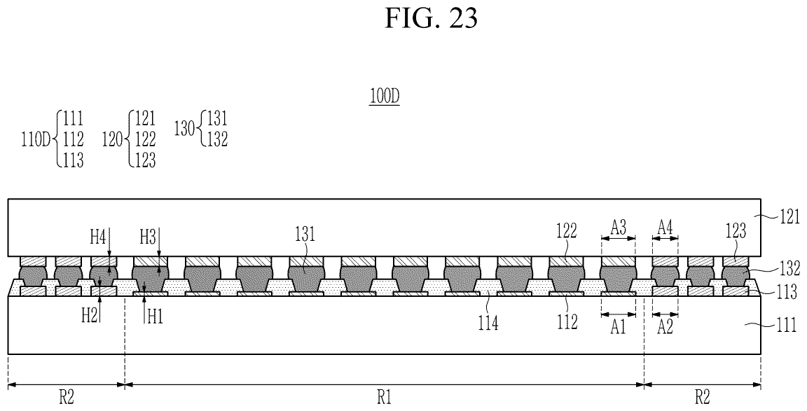

FIG. 18 is a cross-sectional view showing a substrate 110D according to further embodiments. References numerals used herein and labeled in FIGS. 1-9 to describe the substrate 110 and the semiconductor package 100 are also used herein and labeled in FIG. 18 to designate similar or corresponding components and features of the substrate 110D and the semiconductor package 100D (FIG. 23).

Referring to FIG. 18, the substrate 110D may include a substrate base 111, first connection pads 112, second connection pads 113, and an insulating member 114.

The first connection pads 112 are located on the upper surface of the substrate base 111. The first connection pads 112 are located in the central region R1. The first connection pads 112 protrude from the substrate base 111. The second connection pads 113 are disposed on the upper surface of the substrate base 111. The second connection pads 113 are located in the peripheral region R2. The second connection pads 113 protrude from the substrate base 111.

The insulating member 114 is disposed on the substrate base 111, on each part of the first connection pads 112, and on each part of the second connection pads 113. The insulating member 114 includes through holes OP for a soldering. The insulating member 114 prevents the first connection members 131 or the second connection members 132 from being short-circuited. The upper surface of each of the first connection pads 112 or the upper surface of each of the second connection pads 113 is exposed from the through holes OP. The insulating member 114 surrounds a portion of the upper surface and the side surface of each of the first connection pads 112, and a portion of the upper surface and the side surface of each of the second connection pads 113. In some embodiments, the insulating member 114 may include a solder resist.

For contents other than those described in the embodiment of FIG. 18, the contents described for the substrate 110 in FIG. 1 and FIG. 2 may be applied.

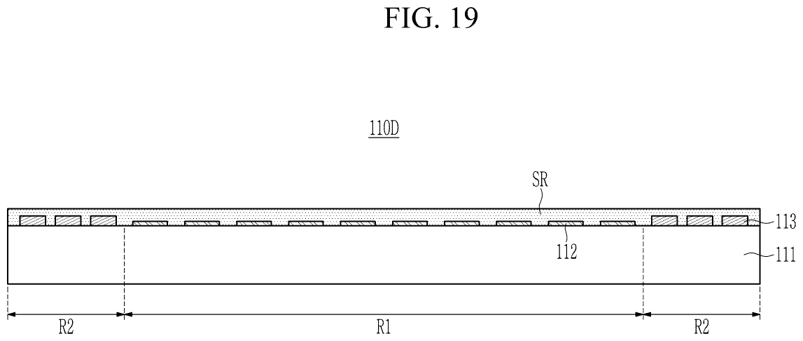

FIG. 19 to FIG. 22 are cross-sectional views to explain a method of manufacturing the substrate 110D of FIG. 18.

FIG. 19 is a cross-sectional view showing a method of forming a solder resist SR on a substrate base 111, first connection pads 112, and second connection pads 113. Before this step, the manufacturing method of the substrate 110 in FIG. 3 to FIG. 8 may be applied in the same way to the manufacturing method of the substrate base 111, the first connection pads 112, and the second connection pads 113.

Referring to FIG. 19, the solder resist SR is coated on the substrate base 111, the first connection pads 112, and the second connection pads 113.

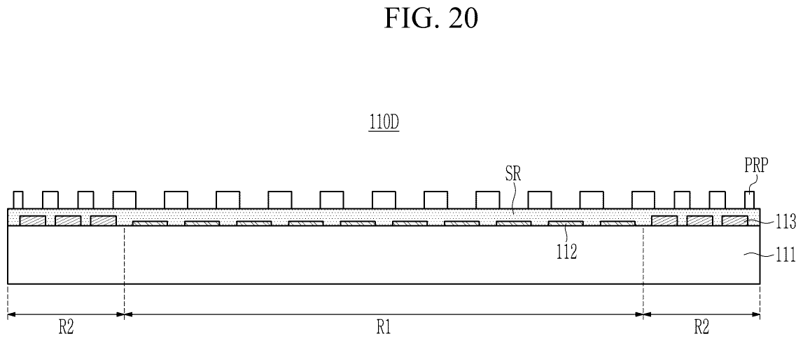

FIG. 20 is a cross-sectional view showing a step of forming a photoresist pattern PRP on the solder resist SR.

Referring to FIG. 20, a photoresist is formed on the solder resist SR. In some embodiments, the photoresist may be formed through a spin coating. In some embodiments, the photoresist may include an organic polymer resin including a photosensitive material. After this, the photoresist is exposed and developed to form a photoresist pattern PRP.

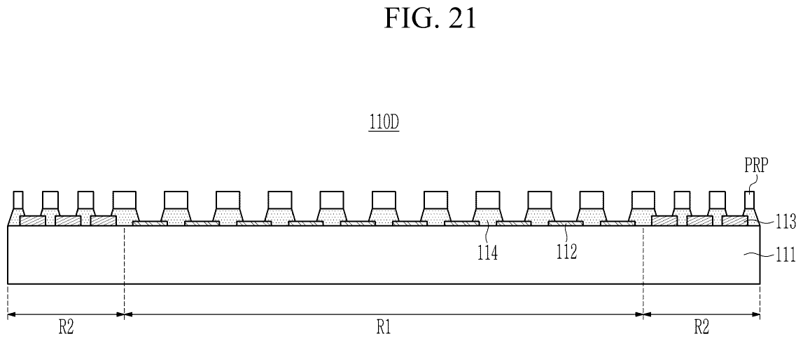

FIG. 21 is a cross-sectional view showing a step for removing a portion of the solder resist SR exposed from the photoresist pattern PRP.

Referring to FIG. 21, by using the photoresist pattern PRP as a mask, the portion of the solder resist SR exposed from the photoresist pattern PRP is exposed, developed, and removed.

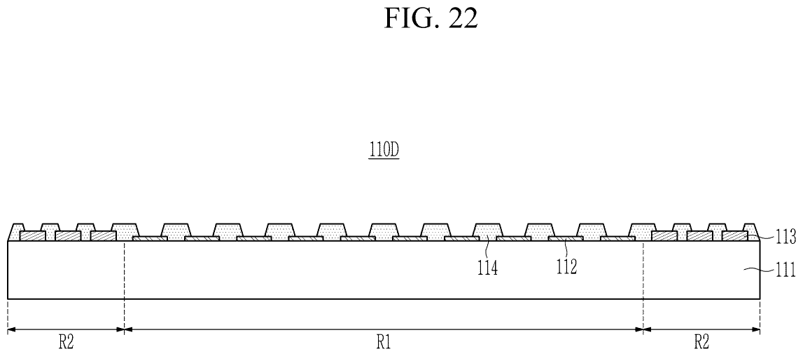

FIG. 22 is a cross-sectional view showing a step for removing the photoresist pattern PRP.

Referring to FIG. 22, the photoresist pattern PRP is removed. In some embodiments, the photoresist pattern PRP may be removed by at least one of etching, ashing, and stripping.

FIG. 23 is a cross-sectional view showing a semiconductor package 100D according to some embodiments.

Referring to FIG. 23, a semiconductor die 120 is mounted on the substrate 110D of FIG. 22 to form the semiconductor package 100D. The semiconductor die 120 is mounted on the substrate 110D by performing a flip chip bonding process.

For the contents other than those described in the embodiment of FIG. 23, the contents described for the substrate 110 in FIG. 1 and FIG. 2 and the contents described for the semiconductor package 100 in FIG. 9 may be applied.

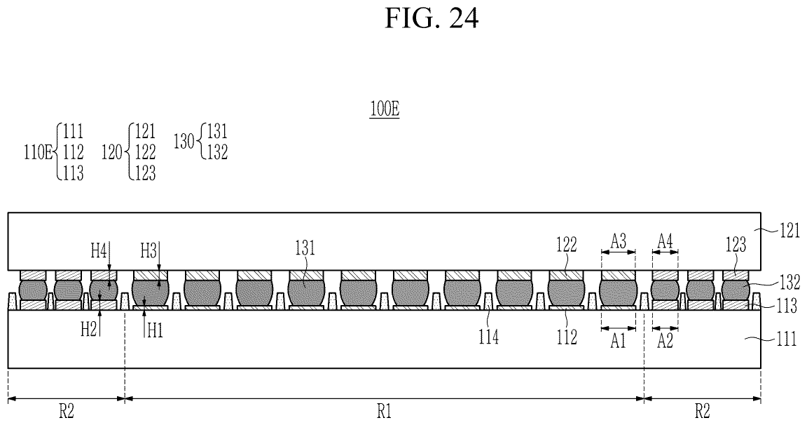

FIG. 24 is a cross-sectional view showing a semiconductor package 100E according to further embodiments.

Referring to FIG. 24, the semiconductor package 100E may include a substrate 110E, first connection members 131, second connection members 132, and a semiconductor die 120. The substrate 110E may include a substrate base 111, first connection pads 112, second connection pads 113, and an insulating member 114.

The first connection pads 112 are located on the upper surface of the substrate base 111. The first connection pads 112 are located in the central region R1. The first connection pads 112 protrude from the substrate base 111. The first connection pads 112 are spaced apart from the insulating member 114. Each of the first connection members 131 may cover at least a portion of side surface of each of the respective first connection pads 112.

The second connection pads 113 are disposed on the upper surface of the substrate base 111. The second connection pads 113 are located in the peripheral region R2. The second connection pads 113 protrude from the substrate base 111. The second connection pads 113 are spaced apart from the insulating member 114. Each of the second connection members 132 may cover at least a portion of side surface of each of the respective second connection pads 113.

The insulating member 114 is disposed on the substrate base 111. The insulating member 114 includes through holes OP (corresponding to OP in FIG. 18) for the soldering. The insulating member 114 prevents the first connection members 131 or the second connection members 132 from being short-circuited. The upper and side surfaces of each of the first connection pads 112 or the second connection pads 113 are exposed from the through holes OP. The insulating member 114 is spaced apart from each of the first connection pads 112 and from each of the second connection pads 113. In some embodiments, the insulating member 114 may include a solder resist.

For contents other than those described in the embodiment of FIG. 24, the contents described for the substrate 110 in FIG. 1 and FIG. 2 and the contents described for the semiconductor package 100 in FIG. 9 may be applied.

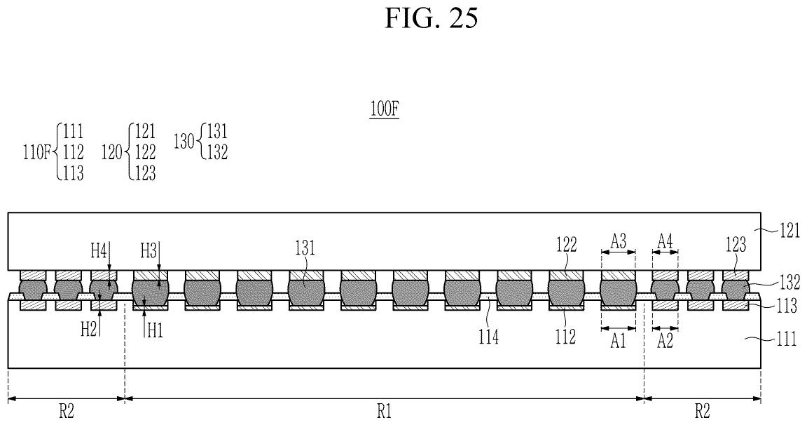

FIG. 25 is a cross-sectional view showing a semiconductor package 100F according to further embodiments. References numerals used herein and labeled in FIGS. 1-9 to describe the substrate 110 and the semiconductor package 100 are also used herein and labeled in FIG. 25 to designate similar or corresponding components and features of the substrate 110F and the semiconductor package 100F.

Referring to FIG. 25, the semiconductor package 100F may include a substrate 110F, first connection members 131, second connection members 132, and a semiconductor die 120. The substrate 110F may include a substrate base 111, first connection pads 112, second connection pads 113, and an insulating member 114. The substrate base 111 includes recessed portions 111R (referring to FIG. 11) on the upper surface thereof. The recessed portions 111R include the first recessed portions 112R (referring to FIG. 11) of the first region R1 and the second recessed portions 113R (referring to FIG. 11) of the second region R2.

Each of the first connection pads 112 is disposed within each of the first recessed portions 112R. Side surfaces of each of the first connection pads 112 extends conformally along the inner side surfaces of each of the first recessed portions 112R. Side surfaces of each of the first connection pads 112 is in contact with the inner side of each of the first recessed portions 112R.

Each of the second connection pads 113 is disposed within a respective one of the second recessed portions 113R. Side surfaces of each of the second connection pads 113 extend conformally along the inner side surfaces of each of the second recessed portions 113R. Side surfaces of each of the second connection pads 113 are in contact with the inner side surfaces of each of the second recessed portions 113R.

The insulating member 114 is disposed on the substrate base 111 excluding the recessed portions. The insulating member 114 includes through holes OP (corresponding to OP in FIG. 18) for the soldering. The insulating member 114 prevents the first connection members 131 or the second connection members 132 from being short-circuited. The upper surface of each of the first connection pads 112 or the upper surface of each of the second connection pads 113 is exposed through the through holes OP. The insulating member 114 is spaced apart from each of the first connection pads 112 and from each of the second connection pads 113. In some embodiments, the insulating member 114 may include a solder resist.

For contents other than those described in the embodiment of FIG. 25, the description of the substrate 110B in FIG. 10 and the contents described for the semiconductor package 100 in FIG. 9 may be applied.

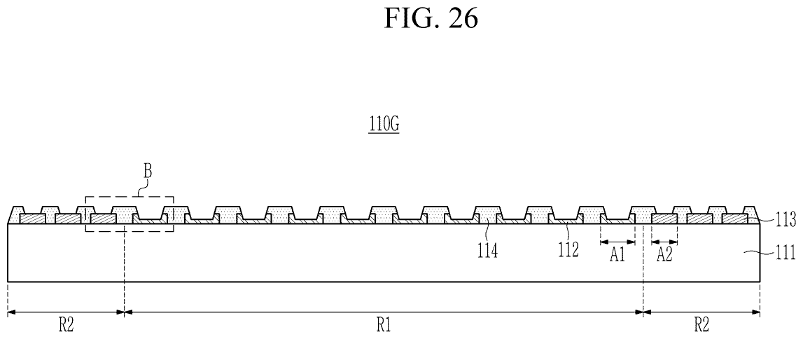

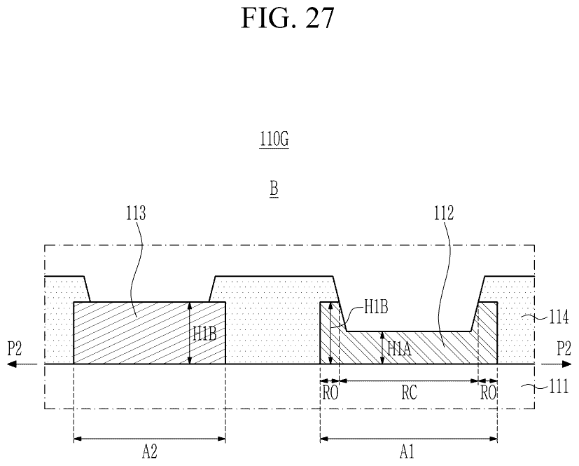

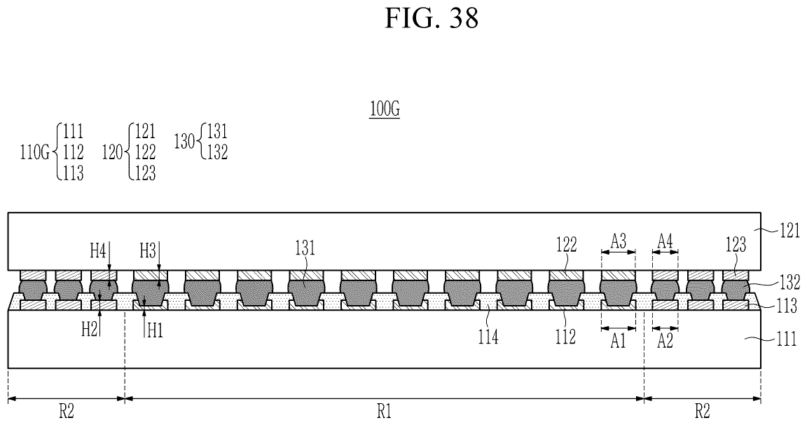

FIG. 26 is a cross-sectional view showing a substrate 110G according to further embodiments. FIG. 27 is an enlarged cross-sectional view of a region B in FIG. 26. References numerals used herein and labeled in FIGS. 1-9 to describe the substrate 110 and the semiconductor package 100 are also used herein and labeled in FIGS. 26 and 27 to designate similar or corresponding components and features of the substrate 110G and the semiconductor package 100G (FIG. 38).

Referring to FIG. 26 and FIG. 27, the substrate 110G may include a substrate base 111, first connection pads 112, second connection pads 113, and an insulating member 114.

The first connection pads 112 are located on the upper surface of the substrate base 111. The first connection pads 112 are located on the central region R1. The first connection pads 112 protrude from the substrate base 111. Each of the first connection pads 112 includes a recessed region RC and a non-recessed region RO around the recessed region RC. The recessed region RC and non-recessed region RO are defined by dividing a reference plane P2 of each among the first connection pads 112. Each of the first connection pads 112 may have a first area A1 in the horizontal direction or reference plane P1. In the recessed region RC, each of the first connection pads 112 may have a first height H1A in the vertical direction. In the non-recessed region RO, each of the first connection pads 112 may have a second height H1B in the vertical direction.

The second connection pads 113 are disposed on the upper surface of the substrate base 111. The second connection pads 113 are located in the peripheral region R2. The second connection pads 113 protrude from the substrate base 111. An upper surface of each of the second connection pads 113 may have a second area A2 in the horizontal direction or plane P1. Each of the second connection pads 113 may have a second height H1B in the vertical direction.

The insulating member 114 is disposed on the substrate base 111, on each part of the first connection pads 112, and on each part of the second connection pads 113. The insulating member 114 includes through holes OP (corresponding to OP in FIG. 18) for a soldering. The insulating member 114 prevents the first connection members 131 or the second connection members 132 from being short-circuited. The upper surface of each of the first connection pads 112 or the upper surface of each of the second connection pads 113 is exposed through the through holes OP. The insulating member 114 surrounds a portion of the upper surface and the side surface of each of the first connection pads 112, and a portion of the upper surface and the side surface of each of the second connection pads 113. In some embodiments, the insulating member 114 may include a solder resist.

For contents other than those described in the embodiment of FIG. 26 and FIG. 27, the contents described for the substrate 110 in FIG. 1 and FIG. 2 may be equally applied.

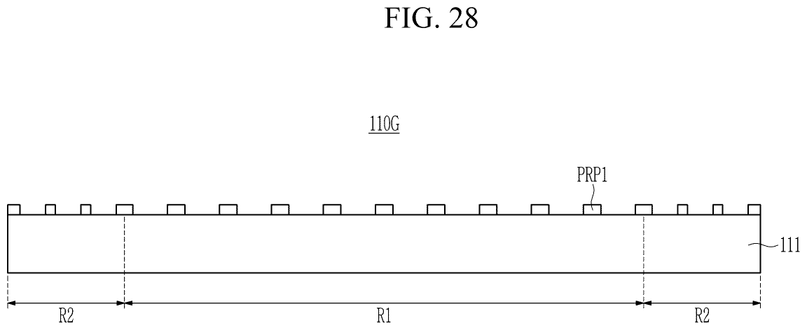

FIG. 28 to FIG. 37 are cross-sectional views to explain a method of manufacturing the substrate 110G of FIG. 26.

FIG. 28 is the cross-sectional view showing a step of forming a first photoresist pattern PRP1 on a substrate base 111.

Referring to FIG. 28, a barrier layer may be formed on the substrate base 111. In some embodiments, the barrier layer may include at least one of titanium, titanium nitride, tantalum, and tantalum nitride. The barrier layer prevents the conductive materials constituting the seed metal layer or the first connection pads 112 from diffusing into the substrate base 111. In some embodiments, the barrier layer may be formed by performing a physical vapor deposition (PVD) process. In some embodiments, the barrier layer may be formed by performing a sputtering process.

Next, a seed metal layer can be formed on the barrier layer. In some embodiments, the seed metal layer may include copper. In some embodiments, the seed metal layer may be formed by an electroless plating. In some embodiments, a cleaning process or a metal catalyst activation pretreatment process may be performed prior to the electroless plating. In some embodiments, the seed metal may be formed by performing a sputtering process.

Next, a photoresist is formed on the seed metal layer. In some embodiments, the photoresist may be formed through a spin coating. In some embodiments, the photoresist may include an organic polymer resin including a photoactive material.

Next, the photoresist is exposed and developed to form the first photoresist pattern PRP1. The first photoresist pattern PRP1 includes openings, each of which may have a shape of an oval, quadrangle, hexagon, or polygon.

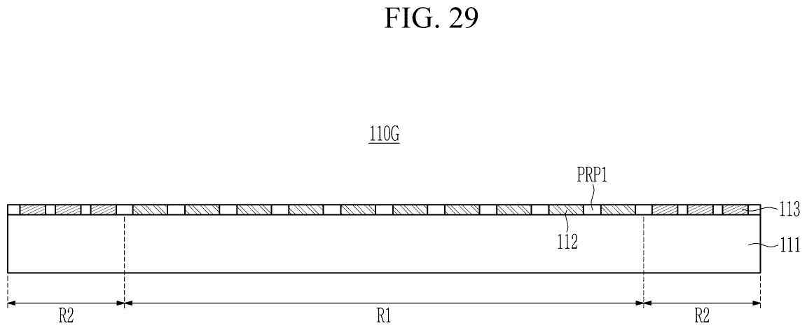

FIG. 29 is the cross-sectional view showing a step of forming each of the first connection pads 112 and each of the second connection pads 113 within each of the openings of the first photoresist pattern PRP1.

Referring to FIG. 29, each of the first connection pads 112 and each of the second connection pads 113 are formed within each of the openings of the first photoresist pattern PRP1. In some embodiments, the first connection pads 112 and the second connection pads 113 may be formed by an electroplating. The first connection pads 112 and the second connection pads 113 are formed by growing a metal layer by an electroplating from the seed metal layer formed first. In some embodiments, an annealing process may be performed after each of the first connection pads 112 and the second connection pads 113 are formed. In some embodiments, the first connection pads 112 and the second connection pads 113 may each include copper.

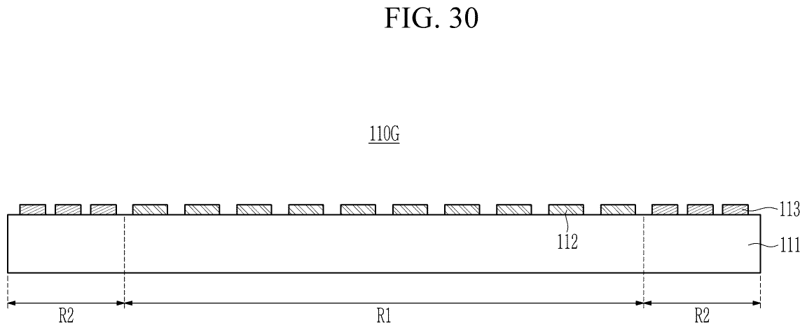

FIG. 30 is a cross-sectional view showing a step to remove the first photoresist pattern PRP1.

Referring to FIG. 30, the first photoresist pattern PRP1 is removed. In some embodiments, the first photoresist pattern PRP1 may be removed by at least one of etching, ashing, and stripping.

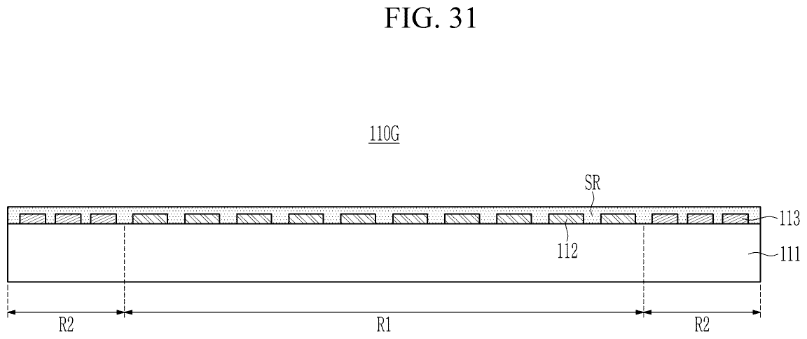

FIG. 31 is the cross-sectional view showing a step of forming a solder resist SR on the substrate base 111, on the first connection pads 112, and on the second connection pads 113.

Referring to FIG. 31, the solder resist SR is coated on the substrate base 111, the first connection pads 112, and the second connection pads 113.

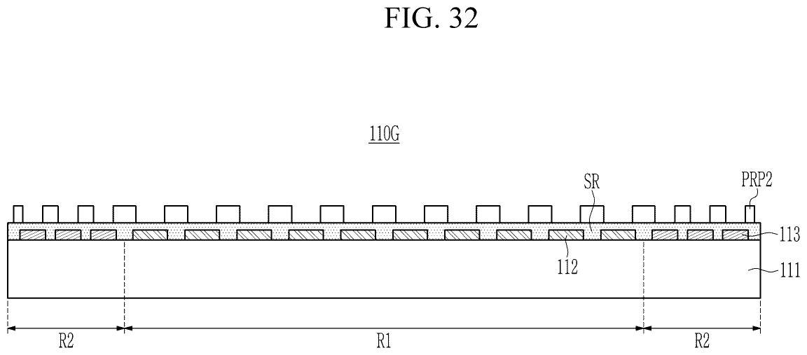

FIG. 32 is the cross-sectional view showing a step of forming the second photoresist pattern PRP2 on the solder resist SR.

Referring to FIG. 32, a photoresist is formed on the solder resist SR. In some embodiments, the photoresist may be formed through a spin coating. In some embodiments, the photoresist may include an organic polymer resin including a photosensitive material. Next, the photoresist is exposed and developed to form a second photoresist pattern PRP2.

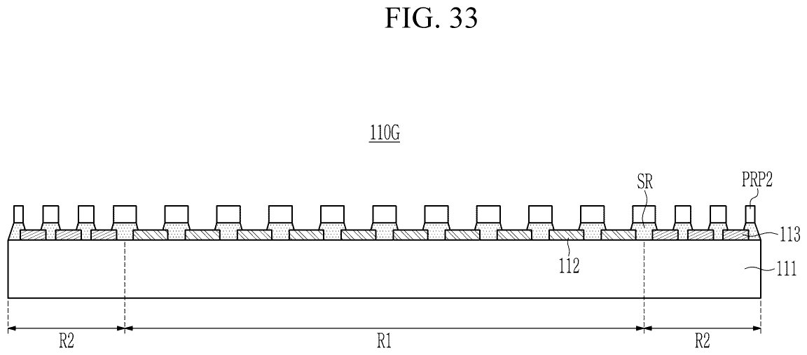

FIG. 33 is a cross-sectional view showing a step for removing the portion of the solder resist SR exposed from the second photoresist pattern PRP2.

Referring to FIG. 33, by using the second photoresist pattern PRP2 as a mask, the portion of solder resist SR exposed from second photoresist pattern PRP2 is exposed, developed, and removed.

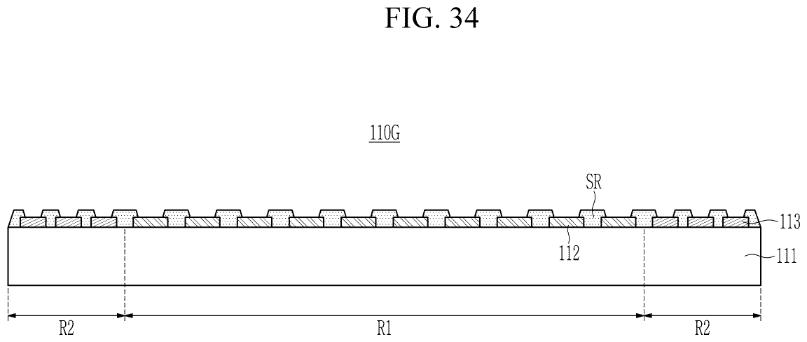

FIG. 34 is the cross-sectional view showing a step for removing the second photoresist pattern PRP2.

Referring to FIG. 34, the second photoresist pattern PRP2 is removed. In some embodiments, the second photoresist pattern PRP2 may be removed by at least one of etching, ashing, and stripping.

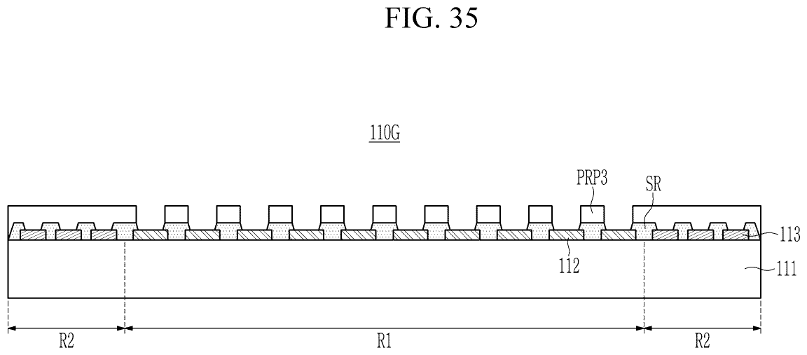

FIG. 35 is a cross-sectional view showing a step of forming a third photoresist pattern PRP3 on the solder resist SR and on the second connection pads 113.

Referring to FIG. 35, a photoresist is formed on the solder resist SR. In some embodiments, the photoresist may be formed through a spin coating. In some embodiments, the photoresist may include an organic polymer resin including a photosensitivity material. Next, the photoresist is exposed and developed to form a third photoresist pattern PRP3.

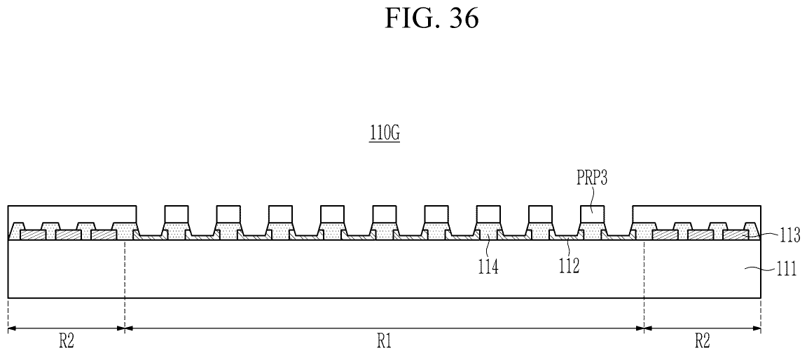

FIG. 36 is the cross-sectional view showing a step for removing each part of the first connection pads 112 exposed from the third photoresist pattern PRP3.

Referring to FIG. 36, by using the third photoresist pattern PRP3 as a mask, each part of the first connection pads 112 exposed from the third photoresist pattern PRP3 is etched. After the etching process, the first connection pads 112 includes the recessed region RC (referring to FIG. 27) and the non-recessed region RO (referring to FIG. 27).

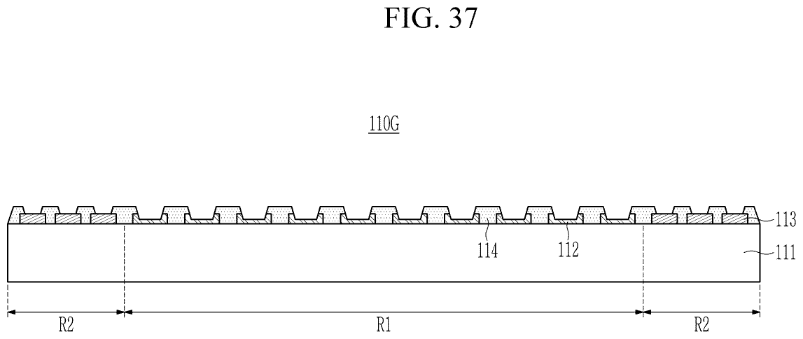

FIG. 37 is the cross-sectional view showing the step for removing the third photoresist pattern PRP3.

Referring to FIG. 37, the third photoresist pattern PRP3 is removed. In some embodiments, the third photoresist pattern PRP3 may be removed by at least one of etching, ashing, and stripping.

FIG. 38 is the cross-sectional view showing some embodiments of the semiconductor package 100G.

Referring to FIG. 38, the semiconductor die 120 is mounted on the substrate 110G of FIG. 37 to form the semiconductor package 100G. The semiconductor die 120 is mounted on the substrate 110G by performing a flip chip bonding process.

For contents other than those described in the embodiment of FIG. 38, the contents described for the substrate 110 in FIG. 1 and FIG. 2 and the contents described for the semiconductor package 100 in FIG. 9 may be applied.

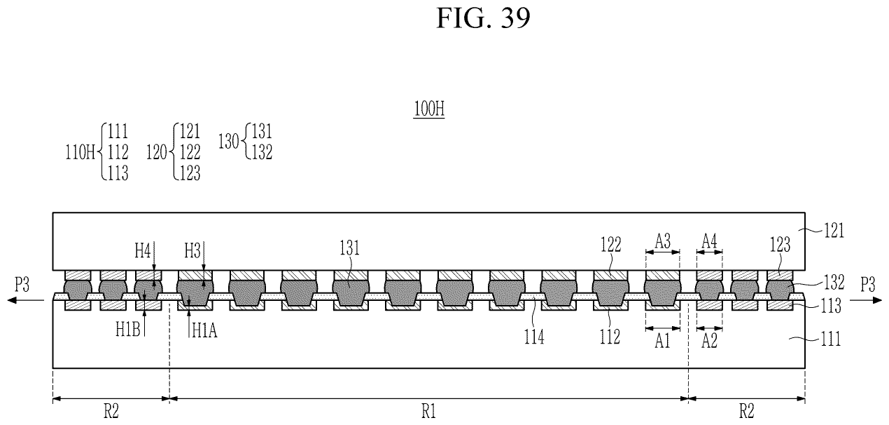

FIG. 39 is a cross-sectional view showing a semiconductor package 100H according to further embodiments. References numerals used herein and labeled in FIGS. 1-9 to describe the substrate 110 and the semiconductor package 100 are also used herein and labeled in FIG. 39 to designate similar or corresponding components and features of the substrate 110H and the semiconductor package 100H.

Referring to FIG. 39, the semiconductor package 100H may include a substrate 110H, first connection members 131, second connection members 132, and a semiconductor die 120. The substrate 110 may include a substrate base 111, first connection pads 112, second connection pads 113, and an insulating member 114. The substrate base 111 includes recessed portions 111R (referring to FIG. 11) on the upper surface thereof. The recessed portions 111R include first recessed portions 112R (referring to FIG. 11) in a first region R1 and second recessed portions 113R (referring to FIG. 11) in a second region R2.

Each of the first connection pads 112 is disposed within a respective one of the first recessed portions 112R. Side surfaces of each of the first connection pads 112 extend conformally along the inner side surfaces of each of the first recessed portions 112R. Side surfaces of each of the first connection pads 112 are in contact with the inner side surfaces of each of the first recessed portions 112R. Each of the first connection pads 112 includes a recessed region RC (corresponding to RC of FIG. 27) and a non-recessed region RO (corresponding to RO of FIG. 27) around the recessed region RC. The recessed region RC and the non-recessed region RO are defined by dividing or sectioning a horizontal reference plane P3 among the first connection pads 112. The reference plane P3 of each of the first connection pads 112 may have a first area A1 in the horizontal direction. In the recessed region RC, each of the first connection pads 112 may have a first height H1A in the vertical direction. In the non-recessed region RO, each of the first connection pads 112 may have a second height H1B in the vertical direction.

Each of the second connection pads 113 is disposed within a respective one of the second recessed portions 113R. Side surfaces of each of the second connection pads 113 extend conformally along the inner side surfaces of each of the second recessed portions 113R. Side surfaces of each of the second connection pads 113 are in contact with the inner side surfaces of each of the second recessed portions 113R. An upper surface of each of the second connection pads 113 may have a second area A2 in the horizontal direction or plane. Each of the second connection pads 113 may have a second height H1B in the vertical direction.

The insulating member 114 is disposed on the substrate base 111 and on each non-recessed region RO of the first connection pads 112. The insulating member 114 includes through holes OP (corresponding to OP in FIG. 18) for a soldering. The insulating member 114 prevents the first connection members 131 or the second connection members 132 from being short-circuited. The upper surface of each recessed region RC of the first connection pads 112 is exposed through the through holes OP. A portion of the upper surface of each of the second connection pads 113 is exposed through the through holes OP. In some embodiments, the insulating member 114 may include a solder resist.

For contents other than those described in the embodiment of FIG. 39, the contents described for the substrate 110 in FIG. 10, the contents described for the semiconductor package 100 in FIG. 9, and the contents described for the first connection pads 112 in FIG. 26 and FIG. 27 may be applied.

While this disclosure has been described in connection with what is presently considered to be practical exemplary embodiments, it is to be understood that the disclosure is not limited to the disclosed embodiments, but, on the contrary, is intended to cover various modifications and equivalent arrangements included within the spirit and scope of the appended claims.

What is claimed is:

1. A semiconductor substrate comprising:
a substrate base, wherein the substrate base includes a first region and a second region around the first region, and the first region and the second region are defined as sections of a reference plane of the substrate base;
a plurality of first connection pads in the first region, wherein an upper surface of each of the plurality of first connection pads has a first area in a horizontal direction, and each of the plurality of first connection pads has a first height in a vertical direction; and
a plurality of second connection pads in the second region, wherein an upper surface of each of the plurality of second connection pads has a second area in the horizontal direction, and each of the plurality of second connection pads has a second height in the vertical direction,
the first area is larger than the second area, and
the first height is less than the second height.

2. The semiconductor substrate of claim 1, wherein:
a difference between the second height and the first height increases as a difference between the first area and the second area increases.

3. The semiconductor substrate of claim 1, wherein:
the plurality of first connection pads and the plurality of second connection pads protrude from the substrate base.

4. The semiconductor substrate of claim 3, further comprising:
an insulating member on the substrate base, around the plurality of first connection pads, and around the plurality of second connection pads.

5. The semiconductor substrate of claim 4, wherein:
the insulating member is spaced apart from each of the plurality of first connection pads, and from each of the plurality of second connection pads.

6. The semiconductor substrate of claim 4, wherein:
the insulating member is in contact with each of the plurality of first connection pads, and each of the plurality of second connection pads.

7. The semiconductor substrate of claim 1, wherein:
the substrate base includes a plurality of recessed portions, and
each of the plurality of first connection pads or each of the plurality of second connection pads is located within a respective one of the plurality of recessed portions.

8. The semiconductor substrate of claim 7, further comprising:
an insulating member on the substrate base, on the plurality of first connection pads, and on the plurality of second connection pads,
the insulating member includes a plurality of through holes,
each of the plurality of first connection pads or each of the plurality of second connection pads is exposed through a respective one of the plurality of through holes.

9. A semiconductor substrate comprising:
a substrate base, wherein the substrate base includes a first region and a second region around the first region, and the first region and the second region are defined as sections of a reference plane of the substrate base;
a plurality of first connection pads on the first region, wherein each of the plurality of first connection pads includes a recessed region and a non-recessed region around the recessed region, and the recessed region and the non-recessed region are defined as sections of a plane of each of the plurality of first connection pads,
each plane of the plurality of first connection pads has a first area in a horizontal direction, and
each of the plurality of first connection pads has a first height in a vertical direction on the recessed region;
a plurality of second connection pads on the second region, wherein an upper surface of each of the plurality of second connection pads has a second area in the horizontal direction, and each of the plurality of second connection pads has a second height in the vertical direction; and
an insulating member on the substrate base, on the plurality of first connection pads, and on the plurality of second connection pads, wherein the insulating member includes a plurality of through holes, and each of the plurality of first connection pads or each of the plurality of second connection pads is exposed through a respective one of the plurality of through holes,
the first area is larger than the second area, and
the first height is less than the second height.

10. The semiconductor substrate of claim 9, wherein:
the plurality of first connection pads and the plurality of second connection pads protrude from the substrate base.

11. The semiconductor substrate of claim 9, wherein:
the substrate base includes a plurality of recessed portions, and
each of the plurality of first connection pads or each of the plurality of second connection pads is located within a respective one of the plurality of recessed portions.

12. The semiconductor substrate of claim 9, wherein:
the insulating member is in contact with the non-recessed region.

13. The semiconductor substrate of claim 9, wherein:
each of the plurality of first connection pads has a third height in the vertical direction in the non-recessed region, and
the third height is the same as the second height.

14. A semiconductor package comprising:
a semiconductor substrate, wherein the semiconductor substrate includes:
a substrate base including a first region and a second region around the first region, and the first region and the second region are defined as sections of a reference plane of the substrate base;
a plurality of first connection pads on the first region, wherein an upper surface of each of the plurality of first connection pads has a first area in a horizontal direction, and each of the plurality of first connection pads has a first height in a vertical direction; and
a plurality of second connection pads on the second region, wherein an upper surface of each of the plurality of second connection pads has a second area in the horizontal direction, and each of the plurality of second connection pads has a second height in the vertical direction, the first area is larger than the second area, and the first height is less than the second height,
a semiconductor die on the semiconductor substrate, wherein the semiconductor die includes a plurality of third connection pads and a plurality of fourth connection pads;
a plurality of first connection members between the semiconductor substrate and the semiconductor die, wherein each of the plurality of first connection members connects a respective one of the plurality of first connection pads to a respective one of the plurality of third connection pads; and
a plurality of second connection members between the semiconductor substrate and the semiconductor die, wherein each of the plurality of second connection members connects a respective one of the plurality of second connection pads to a respective one of the plurality of fourth connection pads.

15. The semiconductor package of claim 14, wherein:
a bottom surface of each of the plurality of third connection pads has a third area in the horizontal direction,
a bottom surface of each of the plurality of fourth connection pads has a fourth area in the horizontal direction, and
the third area is larger than the fourth area.

16. The semiconductor package of claim 14, wherein:
each of the plurality of third connection pads has a third height in the vertical direction,
each of the plurality of fourth connection pads has a fourth height in the vertical direction, and
the third height is the same as the fourth height.

17. The semiconductor package of claim 14, wherein:
the plurality of first connection pads are configured to route an electric power transmitted to the semiconductor die.

18. The semiconductor package of claim 14, wherein:
each of the plurality of second connection pads are configured to route a signal transmitted to or from the semiconductor die.

19. The semiconductor package of claim 14, wherein:
each of the first connection members covers at least a part of a side of a respective one of the plurality of first connection pads.

20. The semiconductor package of claim 14, wherein:
the semiconductor substrate includes a printed circuit board (PCB), an embedded trace substrate (ETS), a board, an interposer, or a bridge die.
